(19) United States
(12) Patent Application Publication
(10) Pub. No.: US 2008/0078994 A1
(43) Pub. Date: Apr. 3, 2008

(54) Microelectronic die having electrical connections to allow testing of guard wall for damage and method of testing guard wall for damage

(76) Inventor: Krishna Seshan, San Jose, CA (US)

Correspondence Address: INTEL CORPORATION;c/o INTELLEVATE, LLC, P.O. BOX 52050, MINNEAPOLIS, MN, 55402, US

(21) Appl. No.: 11/529,870

(22) Filed: Sep. 29, 2006

(51) Int. Cl. H01L 23/58

(52) U.S. Cl. 257/48

(57) ABSTRACT

A microelectronic die includes: a die substrate; an integrated circuit supported in an active area of the substrate; a plurality of bond pads disposed at a surface of the substrate, at least some of the bond pads being coupled to the integrated circuit; a guard wall supported in the substrate and surrounding a periphery of the active region; and electrical connections adapted to apply a voltage differential across the guard wall to allow a damage testing of the guard wall.

### FIELD

Embodiments of the present invention relate generally to the field of microelectronic fabrication. More specifically, embodiments of the present invention relate to integrated circuits that include structures, such as guard walls, that are adapted to reduce or prevent damage to the integrated circuit.

### BACKGROUND

In certain integrated circuits, the terminal metal layer of the same includes a continuous guard wall that surrounds a die active region of the integrated circuit (IC). The guard wall is a grounded metal shield that protects the die active region from damages. Damages, among other things, include invasion by foreign impurities, such as sodium and magnesium existing in the environment, and certain mechanical damages, including micro-cracks that may be produced when a wafer is cut into dices. Micro-cracks propagate to die active regions of the chips producing damages thereto.

FIG. 1 illustrates an example of a prior art die in a top plan view. As shown in FIG. 1, a die 100 has a guard wall 104 surrounding the die active region 101 of the die delimited by a broken line. Bond pads 102 of the die are shown as having been provided in the active area 101. Guard wall 104 protects the die active areas 101a and 101b from damages as noted above.

Present state of the art guard walls are not robust enough to withstand the various forces exerted to the IC. The guard walls may get broken during reliability testing, specifically during temperature cycling to which the integrated circuit is subjected. Shear forces may be exerted to the guard wall during temperature cycling causing damages particularly at and near the corners of the guard wall where these forces have a more destructive effect. In addition, as low dielectric constant (or “low k”) inter layer dielectric (“ILD”) materials are used in the fabrication of IC's, die singulation from a wafer such as by way of using a saw blade can tend to create cracks in the guard wall and compromise the integrity of the die.

At present, expensive and slow methods such as, for example, electron micrography, such as scanning electron micrography (SEM) or transmission electron micrography (TEM), are used to test for guard wall damage

The prior art fails to provide a cost-effective, expedient and reliable method of testing guard wall damage.

### BRIEF DESCRIPTION OF THE DRAWINGS

FIG. 1 is a top plan view of a microelectronic die of the prior art;

FIG. 3 is a top plan view of a microelectronic die according to a first embodiment;

FIG. 3 is a cross-sectional view along lines A-A of the die of FIG. 3 coupled to a package substrate according to an embodiment;

FIG. 4 is a schematic view of an arrangement to test one or more guard walls in a stack of microelectronic dice shown in cross-section according to an embodiment;

FIG. 5 is a schematic view of an arrangement to test one or more guard walls on an unsingulated wafer according to an embodiment;

FIG. 6 is a schematic view of a system including a stack of dice such as the one shown in FIG. 4.

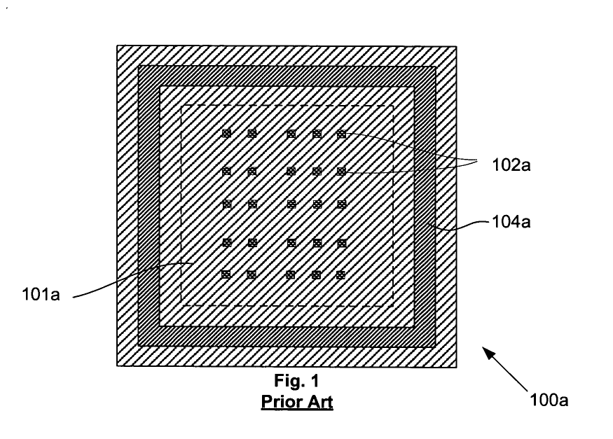

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic die adapted to allow a testing of the guard wall thereof, and a method of testing the guard wall are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to FIGS. X/Y showing an element A/B, what is meant is that FIG. X shows element A and FIG. Y shows element B.

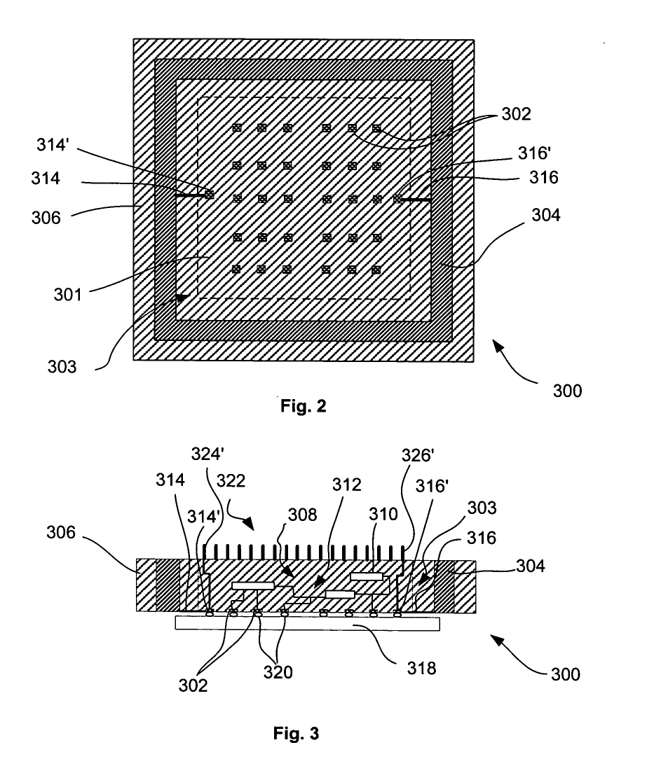

Aspects of this and other embodiments will be discussed herein with respect to FIGS. 3-6, below. The figures, however, should not be taken to be limiting, as they are intended for the purpose of explanation and understanding.

Reference is first made to the embodiment of FIGS. 2 and 3 which show an embodiment of a die 300 including a plurality of bond pads 302 disposed in an active area 301 thereof and a guard wall 304 surrounding the active region 303. By “active region,” what is meant in the context of the instant description is a region of the die including an integrated circuit, that is, devices and layers of interconnect metallization connecting those devices. The active region 303 thus contains the majority of the high-density, active circuitry of the integrated circuit within the die. By “active area,” what is meant in the context of the instant description is a surface area of the die corresponding to a surface of the active region. The die 300 further includes a die substrate 306, and an integrated circuit 308 (see FIG. 3) supported in the substrate 306, and including a plurality of devices 310 disposed in the active region 301, and a plurality of layers of interconnect metallization 312 interconnecting those devices. The bond pads 302 of the embodiment of FIGS. 2 and 3 are disposed at a surface of substrate 306, and, as shown specifically in FIG. 3, at least some of the bond pads 302 are coupled to the integrated circuit 308. By “bond pads,” what is meant in the context of the instant description are contacts on the surface of the die substrate which allow the device to be electrically connected to other devices. The guard wall 304 is shown as being supported in the substrate 306, and surrounds a periphery of the active region 301. The die of the embodiment of FIGS. 2 and 3 further includes respective first and second electrical connections 314 and 316 adapted to carry electricity through the guard wall 304 to allow a damage testing of the same. In the shown embodiment, each of connections 314 and 316 is coupled at one end thereof to a corresponding one of bond pads 314′ and 316′ of the plurality of bond pads 302 within the active area. Each of connections 314 and 316 is further shown as being coupled at an opposite end thereof to a distinct region of the guard wall 304 as shown, the guard wall 304 therefore acting as a resistive element between connections 314 and 316. In the shown embodiment, the electrical connections 314 and 316 each include a trace extending on a surface of the die, one of the traces being adapted to carry electricity to the guard wall 304.

It is noted that embodiments are not limited to an electrical connection that extends on a surface of the die as shown in FIGS. 2 and 3, and include within their scope an electrical connection in the form of an interconnect (that is, in the form of one or more interconnect metallization layers) extending through a thickness of the die substrate (not shown). As will be explained in further detail below, the connections are adapted to allow a damage testing of the guard wall 304. The guard wall and the manners of its fabrication are within the knowledge of persons skilled in the art. According to embodiments, the guard wall 304 may comprise any number of metal and via layers extending through a thickness of the die, such as, for example, five such metal layers, and may be connected to ground or diffusion. The guard wall may, as is well known, include a passivation layer thereon (not shown) including for example a nitride layer over a terminal layer of the guard wall. Formation of the guard wall may includes using well known processes in the art that include, photolithography, patterning, etching, etc.

Referring now to FIG. 3 specifically, a mounting of the die 300 to respective package substrates is shown in cross section along line A-A of FIG. 2. To activate the circuitry within active region 303, and to apply a voltage differential across the guard wall 304 for a damage testing of the same, as will be explained in further detail below, it is necessary to supply voltage signals to bond pads 202 to a package substrate, to which the die 300 is affixed. Die 300 may thus be mounted to package substrate 318 with its top-side facing towards the package substrate. By forming bond pads in the active area 301 of die 300, more bond pads can be placed across the surface of the die than can be placed only within the peripheral region. In addition, active circuitry which underlies bond pads 302 can be directly coupled to its nearest bond pad using relatively short interconnect lines. This minimizes the resistive, capacitive, and inductive effects associated with routing interconnect lines over long distances, improving speed performance.

In order to mount die 300 to package substrate 318, solder balls 320 may be placed on each of bond pads 302 to electrically couple each bond pad 302 to its corresponding solder ball on the package substrate 318. Each corresponding solder ball on package substrate 318 is, in turn, coupled to an external pin 322. Thus, each of bond pads 314′ and 316′ of the bond pads 302 may connected to a corresponding external pin in the form of respective pins 324′ and 326′ on the backside of die 300. In this manner, according to an embodiment, each of electrical connections 314 and 316 connected to a distinct region of guard wall 300 may connect the guard wall to respective pins 324′ and 326′. The packaged die 300 of FIG. 3 may be placed within a socket in order to electrically couple external pins 322 to drivers that supply the necessary voltage signal to activate integrated circuit device 308. Thus, the embodiment of FIG. 3 allows the application of a voltage differential across guard wall 304 in order to allow a damage testing of the same, as will be explained in further detail as the description progresses.

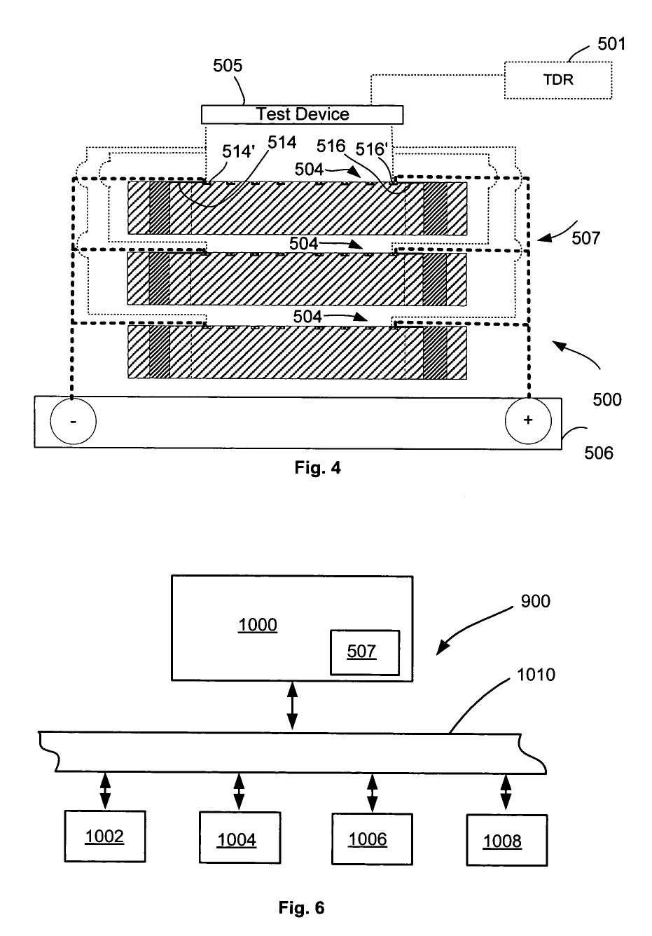

Referring next to FIG. 4, an arrangement 507 is shown for testing damage of the guard walls of a stack of microelectronic dice according to one embodiment. As seen in FIG. 4, a stack 511 of microelectronic dice according to an embodiment may include a plurality of dice 500 similar to die 300 of FIG. 3 described above. However, embodiments are not so limited, and include within their scope a stack including, by way of example only, a single die configured similar to die 300 of FIG. 3, or a die of any configuration where an electrical connection is adapted to carry electricity to the guard wall to allow a damage testing of the same. A stack according to embodiments is not limited to a vertical stack, but includes within its scope a horizontal stack of a stack of any other configuration. A stack of dice according to embodiments, such as, for example, stack 511 of FIG. 4, may comprise a multi-chip module (MCM) comprising any of different types of dice, such as, dynamic random access memory (DRAM), static random access memory (SRAM) and FLASH memory chips, as well as dice having other types of functions such as analog-to-digital converter (ADC) dice, microprocessors, and field programmable gate arrays (FPGAs). Typically, the stacked dice have electrical contacts which are coupled in common or in parallel to contacts on a package substrate of the stack, as is well known in the art. The dice in a stack according to embodiments, such as stack 511 of FIG. 4, may either be directly attached to one another, for example via an attachment of facing active areas thereof, via various ball-grid array connections and interposers, via wire bonds attached to their bond pads, or in any other manner as would be within the knowledge of the skilled person. In the alternative, spacers may be provided between the dice in a stack according to embodiments, such as, for example, a planar silicon spacer with a conductive surface and upwardly facing bond pads. In addition, an interconnection of the individual bond pads of each die in the stack with corresponding bond pads on the package substrate of the stack may occur according to any one of well known methods, such as, for example, through a C4 connection or by way of wire bonding. Stack 511 of FIG. 4 is thus merely a schematic representation of an embodiment of a stack, and may include any one of well known electrical coupling configurations between the dice and between each of the dice and a package substrate (not shown). In turn, the package substrate and/or any of the dice may include pads, pins, solder balls or any other well known features to allow connection of the dice within the stack 511 to external devices, such as, for example, a voltage differential supply source or voltage device.

Referring still to FIG. 4, the arrangement 507 for testing damage to guard walls 304 in stack 511 includes a test device 505. In the shown arrangement, test device 505 is adapted to be coupled (as shown in broken lines) to each of the guard walls 504. Thus, test device 505 may be coupled to guard wall 504 via bond pads 514′ and 516′. A coupling of test device 505 to the guard walls 504 is shown in FIG. 4 in broken lines to suggest that a test device may either, according to one embodiment, be sequentially coupled to each of guard walls 504 to sequentially test for damage to the same, or that a test device may, according to another embodiment, be simultaneously coupled to each of the guard walls 504 to allow a simultaneous testing of damage to the guard walls 504. It is further noted that an arrangement to test according to embodiments is not limited to the use of a single test device, coupled either sequentially or simultaneously, to guard walls 504, and includes within its scope the use of up to as many test devices to the guard walls in a die stack as there may exist guard walls within the stack, each test device being coupled to a corresponding one of the guard walls (not shown). In addition, a coupling of the test device 505 to a guard wall according to embodiments may encompass any coupling to allow a testing of an electrical behavior of a guard wall by the test device 505. By “electrical behavior” of a guard wall, what is meant in the context of the instant description is a measurable behavior and/or characteristic of a guard wall in the presence of a voltage differential applied across any two distinct sections of the guard wall, such as, for example, across bond pads 514′ and 516′ of guard wall 504. For example, “electrical behavior” of the guard wall 504 as used herein may refer to a resistance of the guard wall across bond pads 514′ and 516′, an electrical current flowing through the guard wall across bond pads 514′ and 516′, a voltage differential measured across bond pads 514′ and 516′, an inductance measured across bond pads 514′ and 516′, or a capacitance measured across bond pads 514′ and 516′. According to one embodiment, the test device may include a test tape to measure current across a guard wall being tested, resistance of the guard wall and voltage across the guard wall.

The arrangement 507 of FIG. 4 further includes a voltage device 506 electrically coupled to each guard wall 504 to apply a voltage differential thereacross. In the shown arrangement, voltage device 506 is adapted to be coupled (as shown in broken lines that are in bolder format than the broken lines connecting test device 505 to the guard walls) to each of the guard walls 504. Thus, voltage device 506 may be coupled to guard wall 504a via bond pads 514′ and 516′. A coupling of voltage device 506 to the guard walls 504 is shown in FIG. 4 in broken lines to suggest that a voltage device may either, according to one embodiment, be sequentially coupled to each of guard walls 504 to sequentially apply a voltage differential across the same, or that a voltage device may, according to another embodiment, be simultaneously coupled to each of the guard walls 504 to apply a voltage differential simultaneously to the guard walls 504. It is further noted that an arrangement to test according to embodiments is not limited to the use of a single voltage device, coupled either sequentially or simultaneously, to apply voltage across guard walls 504, and includes within its scope the use of up to fas many voltage devices to the guard walls in a die stack as there may exist guard walls within the stack, each voltage device being coupled to a corresponding one of the guard walls (not shown).

It is noted that a connection of test device 505, voltage device 506 and diffusion to individual ones of the guard walls may be effected through well known contact elements on a package substrate supporting the dice, such as, for example, as noted above, through pads, pins, solder balls, etc. Thus, FIG. 4 merely shows a schematic coupling to guard walls 504, such connections being physically achievable in a number of well known configurations as noted above. Arrangement 507 may further optionally include a time delay reflectometer (TDR) 501 coupled to the test device 505, and adapted, in a well know manner, to indicate a location of damage to one or more of guard walls 504.

In operation, the arrangement 507 of FIG. 4 is first activated according to a method embodiment such that the voltage device 506 applies a voltage differential across one or more of the guard walls 504 to be tested for damage. Thereafter, the method embodiment includes using the test device 505 to sense any deviation of an actual electrical behavior or the guard wall(s) to be tested with respect to an expected electrical behavior to determine damage to the guard wall. By “expected electrical behavior” what is meant in the context of the instant description is an electrical behavior of the guard wall that would occur in the case of an undamaged guard wall. In this manner, test device 505 would be calibrated to indicate damage to a guard wall being tested for example by: (1) sensing an electrical current through the guard wall upon application of a voltage differential thereto by voltage device 506; and (2) comparing the sensed electrical current with an expected electrical current that would have flowed through the guard wall absent the damage. A deviation or difference between the sensed or actual electrical behavior and the expected electrical behavior may suggest damage to the guard wall. The test device 507 may, according to one embodiment, be calibrated such that, where the noted deviation is equal to or above a predetermined threshold value, such test device would indicate that damage to a guard ring has been detected. If the comparison by the test device 505 would indicate damage, then, optionally, a TDR device such as TDR 501 would be used to pinpoint an exact location of the damaged guard wall and/or an exact location of the damage on a given guard wall being tested. Thus, where for example guard walls 504 are being tested simultaneously for damage, a TDR could be used according to an embodiment to pinpoint which of the guard walls 504 had sustained the damage, and where on such guard wall(s) the damage is located.

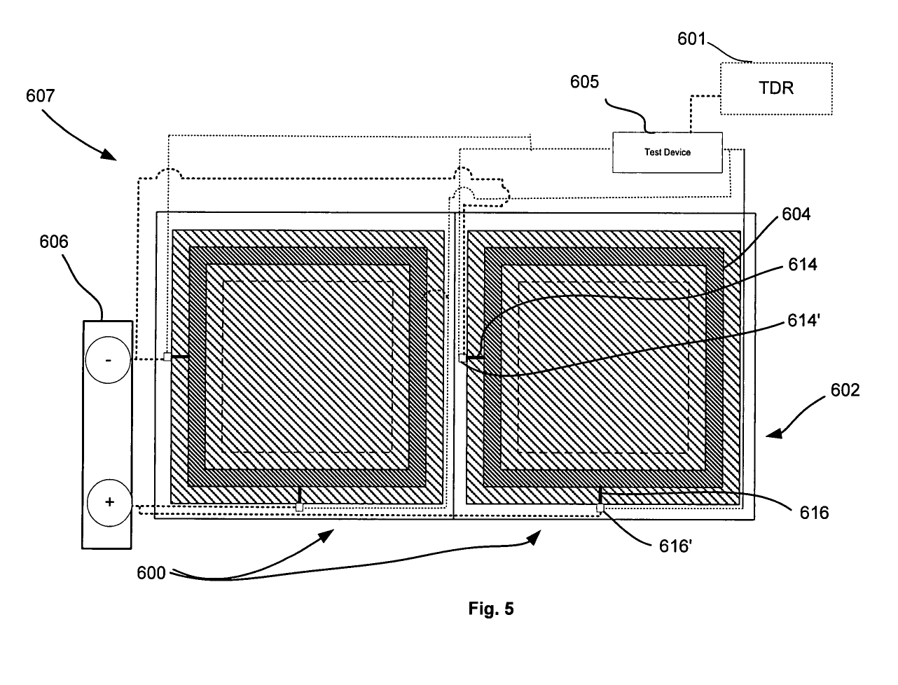

Referring now to FIG. 5, an alternative arrangement 607 is shown for testing damage to a guard wall of a die which is still part of an unsingulated wafer. Thus, as seen in FIG. 5, a portion 602 of an unsingulated wafer is shown (hereinafter “wafer portion 602”) including microelectronic dice according to an embodiment. The wafer portion 602 may include a plurality of dice 600 each being similar to die 300 of FIG. 3 (bond pads not shown in FIG. 500). However, embodiments are not so limited, and include within their scope a wafer having dice of any configuration or configurations where electrical connections are adapted to apply a voltage differential across the guard wall to allow damage testing of the same. In the shown embodiment of an unsingulated wafer, the wafer includes dice 600 each including a guard wall 604 surrounding an active area of the die. Each of the dice further includes an electrical connection 614 coupled at one end thereof to a test pad 614′ in the active area, and at another end thereof to the guard wall 604. Each of the dice also includes an electrical connection 616 coupled at one end thereof to a test pad 616′ and at another end thereof to the guard wall 604 as shown. The arrangement 607 further includes a test device 605, which in the shown embodiment, is adapted to be coupled (as shown in broken lines) to the guard wall 604 of each die 600. Thus, although FIG. 5 shows a coupling of test device 605 to only two of the dice 600 on wafer portion 602, embodiments comprise within their scope a coupling of a test device such as test device 605 to any number of the dice 600 on a wafer. In addition, it is noted that a coupling of test device 602 is shown in FIG. 5 in broken lines to suggest that a test device may, according to one embodiment, be sequentially coupled to each of guard walls 604 to sequentially test for damage to the same, or that a test device may, according to another embodiment, be simultaneously coupled to each of the guard walls 604 to allow a simultaneous testing of damage to the guard walls 604. It is further noted that an arrangement to test according to embodiments is not limited to the use of a single test device, coupled either sequentially or simultaneously, to guard walls 604, and includes within its scope the use of up to as many test devices to the guard walls on a wafer as there may exist guard walls on the wafer, each test device being coupled to a corresponding one of the guard walls (not shown). In addition, a coupling of the test device 605 to a guard wall according to embodiments may encompass any coupling to allow a testing of an electrical behavior of a guard wall by the test device 605. According to one embodiment, the test device may include a test tape to measure current across a guard wall being tested, resistance of the guard wall and voltage across the guard wall.

The arrangement 607 of FIG. 5 further includes a voltage device 606 electrically coupled to each guard wall 604 to apply a voltage differential thereacross. In the shown arrangement, voltage device 606 is adapted to be coupled (as shown in broken lines that are in bolder format than the broken lines connecting test device 605 to the guard walls) to each of the guard walls 304. Thus, voltage device 606 may be coupled to guard wall 604 via test pads 614′ and 616′ on streets 615 of the wafer. A coupling of voltage device 606 to the guard walls 604 is shown in FIG. 5 in broken lines to suggest that a voltage device may, according to one embodiment, be sequentially coupled to each of guard walls 604 to sequentially apply a voltage differential across the same, or that a voltage device may, according to another embodiment, be simultaneously coupled to each of the guard walls 604 to apply a voltage differential simultaneously to the guard walls 604. It is further noted that an arrangement to test according to embodiments is not limited to the use of a single voltage device, coupled either sequentially or simultaneously, to apply voltage across guard walls 604, and includes within its scope the use of up to as many voltage devices to the guard walls on a wafer as there may exist guard walls on the wafer, each voltage device being coupled to a corresponding one of the guard walls (not shown).

It is noted that a connection of test device 604, voltage device 606 and diffusion to individual ones of the guard walls may be effected through well known contact elements on a package substrate supporting the dice, such as, for example, as noted above, through pads, pins, solder balls, etc. Thus, FIG. 5 merely shows a schematic coupling to guard walls 604, such connections being physically achievable in a number of well known configurations as noted above. Arrangement 607 may further optionally include a time delay reflectometer (TDR) 601 coupled to the test device 605, and adapted, in a well know manner, to indicate a location of damage to one or more of guard walls 604.

In operation, the arrangement 607 of FIG. 5 is first activated according to a method embodiment such that the voltage device 606 applies a voltage differential across one or more of the guard walls 604 to be tested for damage. Thereafter, the method embodiment includes using the test device 605 to sense any deviation of an actual electrical behavior or the guard wall(s) to be tested with respect to an expected electrical behavior to determine damage to the guard wall. In this manner, test device 605 would be calibrated to indicate damage to a guard wall being tested for example by: (1) sensing an electrical current through the guard wall upon application of a voltage differential thereto by voltage device 606; and (2) comparing the sensed electrical current with an expected electrical current that would have flowed through the guard wall absent the damage. A deviation or difference between the sensed or actual electrical behavior and the expected electrical behavior may suggest damage to the guard wall. The test device 607 may, according to one embodiment, be calibrated such that, where the noted deviation is equal to or above a predetermined threshold value, such test device would indicate that damage to a guard ring has been detected. If the comparison by the test device 605 would indicate damage, then, optionally, a TDR device such as TDR 501 would be used to pinpoint an exact location of the damaged guard wall and/or an exact location of the damage on a given guard wall being tested. Thus, where for example guard walls 604 are being tested simultaneously for damage, a TDR could be used according to an embodiment to pinpoint which of the guard walls 604 had sustained the damage, and where exactly on such guard wall(s) the damage would be located.

Advantageously, embodiments allow for a way to test for damage to guard walls of microelectronic dice, even after a plurality of dice may have been packaged. Thus embodiments provide an electrical connection scheme that allows an integrity of a guard wall to be tested even after packaging and before reliability testing. No such capacity exists as of now.

Referring to FIG. 6, there is illustrated one of many possible systems 900 in which embodiments of the present invention may be used. In one embodiment, the electronic assembly 1000 may include a microelectronic package such as stack 507 of FIG. 4. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 6, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic die comprising:
a die substrate;
an integrated circuit supported in an active area of the substrate;
a plurality of bond pads disposed at a surface of the substrate, at least some of the bond pads being coupled to the integrated circuit;
a guard wall supported in the substrate and surrounding a periphery of the active region; and
electrical connections adapted to apply a voltage differential across the guard wall to allow a damage testing of the guard wall.

2. The die of claim 1, wherein the electrical connections are coupled to respective test pads on a wafer including the die thereon.

3. The die of claim 1, wherein the electrical connections are coupled to respective bond pads of the plurality of bond pads.

4. The die of claim 1, wherein the electrical connections comprise:
a first trace connected to the guard wall and adapted to carry electricity thereto; and
a second trace connected to the guard wall and adapted to carry electricity therefrom.

5. The die of claim 1, wherein the electrical connections comprise traces extending on a surface of the die.

6. The die of claim 1, wherein the electrical connections comprise interconnect metallization layers extending through a thickness of the die substrate.

7. A stack of microelectronic dice including at least one die according to claim 1.

8. The stack of claim 7, wherein the at least one die comprises all dice in the stack.

9. The stack of claim 7, wherein the electrical connection of the at least one die comprise interconnect metallization layers extending through a thickness of the die substrate.

10. The stack of claim 9, wherein the electrical connections of the at least one die comprise pins extending from the interconnect metallization layers.

11. The stack of claim 7, further including a package substrate electrically coupled to the stack.

12. The stack of claim 11, wherein the electrical connections are connected to respective pins extending from a surface of the package.

13. An arrangement to test damage to the guard wall of the die of claim 1, the arrangement comprising:
a test device coupled to the guard wall through the electrical connections, the test device being adapted to measure a deviation of an actual electrical behavior of the guard wall with an expected electrical behavior of the guard wall to indicate damage thereto; and
a voltage device coupled to the guard wall through the electrical connections and adapted to supply a voltage differential across the guard wall.

14. The arrangement of claim 13, wherein the test device is adapted to sense at least one of a current, a voltage and a resistance across the guard wall to test damage to the guard wall.

15. The arrangement of claim 13, wherein the test device is adapted to indicate damage to the guard wall when the deviation is above a predetermined threshold deviation value.

16. The arrangement of claim 13, further comprising a time delay reflectometer coupled to the test device and adapted to indicate a location of the damage to the guard wall.

17. An arrangement to test damage to guard walls of a plurality of microelectronic dice disposed in a stack, at least some of the dice comprising the die of claim 1, the arrangement comprising:
a test device electrically coupled to each guard wall of said at least some of the dice through corresponding electrical connections of said at least one of the dice; and
a voltage device electrically coupled to said each guard wall through said corresponding electrical connections and adapted to supply a voltage differential across said each guard wall.

18. The arrangement of claim 17, wherein the test device comprises a plurality of test devices, each of the plurality of test devices being electrically coupled to a corresponding one of said each guard wall.

19. The arrangement of claim 17, wherein the voltage device comprises a plurality of voltage devices, each of the plurality of voltage devices being electrically coupled to a corresponding one of said each guard wall.

20. The arrangement of claim 17, wherein the test device is adapted to sense at least one of a current, a voltage and a resistance across said each guard wall to test damage to the guard wall.

21. The arrangement of claim 17, wherein the test device is adapted to indicate damage to the guard wall when the deviation is above a predetermined threshold deviation value.

22. A method of testing damage to a guard wall of a microelectronic die comprising:
applying a voltage differential across the guard wall;
sensing a deviation of an actual electrical behavior of the guard wall with respect to an expected electrical behavior of the guard wall to determine damage to the guard wall.

23. The method of claim 22, further comprising indicating damage to the guard wall when the deviation is above a predetermined threshold deviation value.

24. The method of claim 22, wherein applying a voltage differential comprises applying the voltage differential across one of bond pads of the die, the bond pads being electrically coupled to the guard wall, and test pads on a wafer, the test pads being electrically coupled to the guard wall.

25. The method of claim 22, wherein sensing a deviation comprises measuring at least one of a current, voltage and resistance across the guard wall.

26. The method of claim 22, wherein:
applying a voltage differential comprises applying the voltage differential across a plurality of guard walls of respective ones of a plurality of dice in a stack; and
sensing comprises sensing a deviation of an actual electrical behavior of said each one of the plurality of guard walls with respect to an expected electrical behavior of said each of the plurality of guard walls to determined damage to said each of the plurality of guard walls.

27. The method of claim 22, further comprising locating a damage to the guard wall using time delay reflectometry.

28. A system comprising:
an electronic assembly including:
A microelectronic die comprising:
a die substrate;
an integrated circuit supported in an active area of the substrate;
a plurality of bond pads disposed at a surface of the substrate, at least some of the bond pads being coupled to the integrated circuit;
a guard wall supported in the substrate and surrounding a periphery of the active region; and
electrical connections adapted to apply a voltage differential across the guard wall to allow a damage testing of the guard wall; and
a main memory coupled to the electronic assembly.

29. The system of claim 28, further comprising a stack of microelectronic dice, wherein the microelectronic die is part of the stack.

30. The system of claim 28, wherein the electrical connections are coupled to one of:
respective test pads on a wafer including the die thereon; and
respective bond pads of the plurality of bond pads.
